(19) United States
(12) Patent Application Publication
(10) Pub. No.: US 2025/0056793 A1
(43) Pub. Date: Feb. 13, 2025

(54) MANAGING THREE-DIMENSIONAL SEMICONDUCTIVE DEVICES

(71) Applicant: Yangtze Memory Technologies Co., Ltd., Wuhan (CN)

(72) Inventors: Zhaoyun TANG, Wuhan (CN); Tian LAN, Wuhan (CN); Wenyu HUA, Wuhan (CN)

(21) Appl. No.: 18/477,512

(22) Filed: Sep. 28, 2023

Related U.S. Application Data
(63) Continuation of application No. PCT/CN2023/112602, filed on Aug. 11, 2023.

(51) Int. Cl. H10B 12/00; H01L 23/00; H01L 25/065; H01L 25/18; H10B 80/00

(52) U.S. Cl. CPC H10B 12/482; H01L 24/08; H01L 25/0657; H01L 25/18; H10B 12/02; H10B 12/315; H10B 80/00; H01L 2224/08145; H01L 2924/1431; H01L 2924/1436

(57) ABSTRACT

Systems, devices, and methods for managing three-dimensional semiconductor devices are provided. In one aspect, a method includes: forming strings of memory cells in a first side of a semiconductor substrate having a semiconductor material, forming alternating stripes of the semiconductor material and an isolating material in a second, opposite side of the semiconductor substrate, and forming bit lines in the second side of the semiconductor substrate. The bit lines can be formed by depositing a layer of a metallic material on the alternating stripes of the semiconductor material and the isolating material, and forming each bit line of the bit lines in a corresponding stripe of the semiconductor material of the alternating stripes by forming a composite conductive material based on the metallic material and the semiconductor material in the corresponding stripe of the semiconductor material.

### CROSS-REFERENCE TO RELATED APPLICATIONS

This application is a continuation of International Application No. PCT/CN2023/112602, filed on Aug. 11, 2023, the disclosure of which is hereby incorporated by reference in its entirety.

### TECHNICAL FIELD

The present disclosure relates to semiconductor devices and fabrication processes for semiconductor devices.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array. The memory cells can include vertical transistors.

### SUMMARY

The present disclosure describes methods, devices, systems and techniques for managing three-dimensional (3D) semiconductor devices, e.g., forming vertical transistors and bit lines of the 3D memory devices.

One aspect of the present disclosure features a method including: forming a plurality of strings of memory cells in a first side of a semiconductor substrate along a vertical direction, the semiconductor substrate including a semiconductor material; forming a plurality of alternating stripes of the semiconductor material and an isolating material in a second side of the semiconductor substrate along a horizontal direction perpendicular to the vertical direction, the second side being opposite to the first side along the vertical direction; and forming a plurality of bit lines in the second side of the semiconductor substrate. Forming the plurality of bit lines includes: depositing a layer of a metallic material on the plurality of alternating stripes of the semiconductor material and the isolating material; and forming each bit line of the plurality of bit lines in a corresponding stripe of the semiconductor material of the plurality of alternating stripes by forming a composite conductive material based on the metallic material and the semiconductor material in the corresponding stripe of the semiconductor material.

In some implementations, forming the composite conductive material based on the metallic material and the semiconductor material in the corresponding stripe of the semiconductor material includes: annealing the metallic material and the semiconductor material, such that the metallic material reacts with the semiconductor material to form the composite conductive material. There can be no reaction between the isolating material and the metallic material deposited on the isolating material.

In some implementations, the semiconductor material includes silicon, the isolating material includes oxide, and the composite conductive material includes silicide. In some examples, the metallic material includes Nickel (Ni).

In some implementations, the method further includes: after forming the plurality of bit lines in the second side of the semiconductor substrate, removing a residue of the metallic material from the second side of the semiconductor substrate. In some implementations, removing a residue of the metallic material from the second side includes: wet etching the residue of the metallic material.

In some implementations, forming the plurality of alternating stripes of the semiconductor material and the isolating material in the second side of the semiconductor substrate includes: thinning the semiconductor substrate from the second side of the semiconductor substrate to expose the plurality of alternating stripes of the semiconductor material and the isolating material. The method can further include: implanting ions into the second side of the semiconductor substrate. Forming the composite conductive material based on the metallic material and the semiconductor material in the corresponding stripe of the semiconductor material can include: forming the composite conductive material based on the metallic material and the semiconductor material with the implanted ions.

In some implementations, implanting the ions into the second side of the semiconductor substrate includes: implanting semiconductor ions into the second side of the semiconductor substrate; implanting N+ type ions into the second side of the semiconductor substrate; and activating the implanted N+ type ions with the implanted semiconductor ions under an activation temperature.

In some implementations, the semiconductor material includes silicon, the semiconductor ions include Germanium (Ge) ions, and the N+ type ions include arsenic (As) ions or phosphorus (P) ions.

In some implementations, the activation temperature is lower than a nominal temperature for activating the N+ type ions without implanting the semiconductor ions. In some examples, the nominal temperature is about 900° C., and where the activation temperature is in a range from about 500° C. to about 600° C.

In some implementations, thinning the semiconductor substrate from the second side of the semiconductor substrate includes: etching the semiconductor material in the second side of the semiconductor substrate; and polishing a top surface of the etched semiconductor material in the second side of the semiconductor substrate.

In some implementations, each memory cell of the plurality of strings of memory cells includes a vertical transistor along the vertical direction. Forming the plurality of strings of memory cells includes: forming a gate terminal of the vertical transistor by depositing at least one metallic layer on an inner surface of a trench along the vertical direction; forming a first terminal of the vertical transistor by implanting the ions from the first side of the semiconductor substrate; and forming a second terminal of the vertical transistor by implanting the ions into the second side of the semiconductor substrate. In some examples, the first terminal is a source terminal, and the second terminal is a drain terminal.

In some implementations, each of the plurality of bit lines is formed on the second terminal of the vertical transistor and is coupled to the second terminal of the vertical transistor.

In some implementations, each memory cell of the plurality of strings of memory cells further includes a capacitor coupled to the vertical transistor. Forming the plurality of strings of memory cells can include: forming the capacitor before forming the vertical transistor, the capacitor being over the vertical transistor along the vertical direction.

In some implementations, forming the plurality of strings of memory cells includes: forming gate terminals of a pair of independent vertical transistors in a same trench along the vertical direction, the gate terminals being separated by an isolating material along a third direction perpendicular to the vertical direction and the horizontal direction.

In some implementations, the method further includes: forming an isolating region between adjacent pairs of independent vertical transistors along the third direction.

In some implementations, the plurality of strings of memory cells and the plurality of bit lines are formed in an array die. The method further includes: integrating a control die with the array die by bonding the first side of the semiconductor substrate with a front side of the control die and conductively coupling one or more conductive lines of the array die to a control circuit in the front side of the control die.

Another aspect of the present disclosure features a semiconductor device, including: a plurality of strings of memory cells in a first side of a semiconductor substrate along a vertical direction, the semiconductor substrate including a semiconductor material; and a plurality of bit lines in a second side of the semiconductor substrate, the second side being opposite to the first side along the vertical direction, where adjacent bit lines of the plurality of bit lines are separated by an isolating material along a horizontal direction perpendicular to the vertical direction. The plurality of bit lines are made of a composite conductive material that is based on the semiconductor material, and the plurality of bit lines are on a layer of the semiconductor material with implanted ions.

In some implementations, the implanted ions include semiconductor ions and N+ type ions. In some examples, the semiconductor material includes silicon, the semiconductor ions include Germanium (Ge) ions, the N+ type ions include arsenic (As) ions or phosphorus (P) ions, and the composite conductive material includes silicide.

In some implementations, each memory cell of the plurality of strings of memory cells includes a vertical transistor along the vertical direction, and a portion of the layer of the semiconductor material with the implanted ions is configured to be a terminal of the vertical transistor and to be conductively coupled to a corresponding bit line.

In some implementations, gate terminals of a pair of independent vertical transistors are in a same trench along the vertical direction and separated by an isolating material along a third direction perpendicular to the vertical direction and the horizontal direction, and an isolating region is between adjacent pairs of independent vertical transistors along the third direction. In some examples, the isolating region includes an air cavity or a cavity filled with a metal material surrounded by the isolating material.

Another aspect of the present disclosure features a system including a memory device and a controller coupled to the memory device and configured to control the memory device. The memory device includes: an array structure including a plurality of strings of memory cells in a first side of a semiconductor substrate along a vertical direction, the semiconductor substrate including a semiconductor material; and a plurality of bit lines in a second side of the semiconductor substrate, the second side being opposite to the first side along the vertical direction, where adjacent bit lines of the plurality of bit lines are separated by an isolating material along a horizontal direction perpendicular to the vertical direction, where the plurality of bit lines are made of a composite conductive material that is based on the semiconductor material, and where the plurality of bit lines are on a layer of the semiconductor material with implanted ions.

Another aspect of the present disclosure features a method including: forming a plurality of strings of memory cells in a first side of a semiconductor substrate along a vertical direction, the semiconductor substrate including a semiconductor material; thinning the semiconductor substrate from a second side of the semiconductor substrate along the vertical direction, the second side being opposite to the first side of the semiconductor substrate; and implanting semiconductor ions into the second side of the semiconductor substrate.

In some implementations, the method further includes: implanting N+ type ions into the second side of the semiconductor substrate and activating the implanted N+ type ions with an activation temperature.

In some implementations, the semiconductor material includes silicon, the semiconductor ions include Germanium (Ge) ions, and the N+ type ions include arsenic (As) ions or phosphorus (P) ions.

In some implementations, the activation temperature is lower than a nominal temperature for activating the N+ type ions without implanting the semiconductor ions.

In some implementations, thinning the semiconductor substrate from a second side of the semiconductor substrate along the vertical direction includes: thinning the semiconductor substrate to expose a plurality of alternating stripes of the semiconductor material and an isolating material. The method further includes: forming a plurality of bit lines in the second side of the semiconductor substrate based on a plurality of stripes of the semiconductor material of the plurality of alternating stripes.

In some implementations, forming the plurality of bit lines in the second side of the semiconductor substrate includes: depositing a layer of a metallic material on the plurality of alternating stripes of the semiconductor material and the isolating material; and forming each bit line of the plurality of bit lines in a corresponding stripe of the plurality of stripes of the semiconductor material by forming a composite conductive material based on the metallic material and the semiconductor material in the corresponding stripe. The metallic material can include Nickel (Ni).

In some implementations, forming the composite conductive material based on the metallic material and the semiconductor material in the corresponding stripe includes: annealing the metallic material and the semiconductor material, such that the metallic material reacts with the semiconductor material to form the composite conductive material. There can be no reaction between the isolating material and the metallic material deposited on the isolating material.

In some implementations, forming the composite conductive material based on the metallic material and the semiconductor material in the corresponding stripe includes: forming the composite conductive material based on the metallic material and the semiconductor material with the activated implanted N+ ions.

In some implementations, each memory cell of the plurality of strings of memory cells includes a vertical transistor along the vertical direction. Forming the plurality of strings of memory cells includes: forming a gate terminal of the vertical transistor by depositing at least one metallic layer on an inner surface of a trench along the vertical direction; forming a first terminal of the vertical transistor by implanting N+ type ions from the first side of the semiconductor substrate; and forming a second terminal of the vertical transistor by implanting the N+ type ions into the second side of the semiconductor substrate. In some examples, the first terminal is a source terminal, and the second terminal is a drain terminal.

Implementations of the present disclosure can provide one or more of the following technical advantages and/or benefits. For example, the techniques enable to form self-aligned bit lines from stripes of a semiconductor material on a back side of a semiconductor substrate, e.g., by forming a composite conductive material (e.g., metallic silicide) based on a metallic material (e.g., Ni) and the semiconductor material (e.g., Si). Moreover, compared to complicated fabrication processes of forming metals for bit lines, forming self-aligned bit lines enables to enlarge a process window, and simplify and/or minimize process steps, e.g., omitting Si recess and polysilicon recess process, oxide punch, and some other processes, which can reduce the fabrication cost and increase the fabrication speed.

In some implementations, first and second terminals (e.g., source and drain terminals) of a vertical transistor are formed on opposite ends of a semiconductor body of the vertical transistor. The first terminal can be formed on a first end of the semiconductor body by implanting N+ type ions from a front side of the semiconductor substrate and activating the N+ type ions in the first end. The second terminal can be formed by implanting N+ type ions from the back side of the semiconductor substrate and activating the N+ type ions in the second end. In some cases, with Germanium (Ge) pre-amorphization implantation (Ge PAI), the activation temperature for the N+ type ions in the second end can be reduced, e.g., from over 900° C. to a low thermal temperature such as 500° C. to 600° C., which can reduce a thermal budget of the process. Moreover, the second terminal of a vertical transistor can be formed by directly implanting N+ type ions into the second end of the semiconductor body of the vertical transistor from the back side of the semiconductor substrate, which can enlarge a process window and reduce fabrication cost.

The techniques can also reduce the thickness requirement of performing chemical-mechanical polishing (CMP) to thin the semiconductor substrate from the back side. Further, the composite conductive material (e.g., silicide) can be formed with self-alignment for bit line metal connection, in combination with forming the first terminal from the front side to lower an OFF current Ioff and to increase an ON current Ion and with forming the second terminal from the back side and forming ohmic contact using N+ doped silicide to increase Ion, which can greatly improve a performance of the vertical transistor, a memory cell including the vertical transistor, and/or the 3D semiconductor device including the memory cell. The techniques enable to simplify or optimize the fabrication process of the 3D semiconductor device and reduce the fabrication cost.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates a cross-sectional view of an example 3D semiconductor device.

FIG. 2 shows a perspective view of an example 3D semiconductor device.

FIG. 3A illustrates a cross-sectional view of an example 3D semiconductor device including vertical transistors and bit lines.

FIG. 3B illustrates a top view of the example 3D semiconductor device of FIG. 3A.

FIG. 4A illustrates an example structure showing forming a terminal of a vertical transistor by implanting N+ type ions from a front side of a semiconductor substrate.

FIG. 4B illustrates another example structure showing forming a terminal of a vertical transistor by implanting N+ type ions from a back side of a semiconductor substrate.

FIGS. 5A-5D show cross-sectional views of structures of a 3D semiconductor device at various stages of a fabrication process.

FIG. 6A shows a cross-sectional view of an example structure before forming bit lines.

FIG. 6B shows a cross-sectional view of an example structure after forming bit lines.

FIG. 7A is a flow chart of an example process of forming a semiconductor device.

FIG. 7B is a flow chart of another example process of forming a semiconductor device, according to one or more implementations of the present disclosure.

FIG. 8 illustrates a block diagram of an example system having one or more semiconductor devices.

Like reference numbers and designations in the various drawings indicate like elements. It is also to be understood that the various exemplary implementations shown in the figures are merely illustrative representations and are not necessarily drawn to scale.

### DETAILED DESCRIPTION

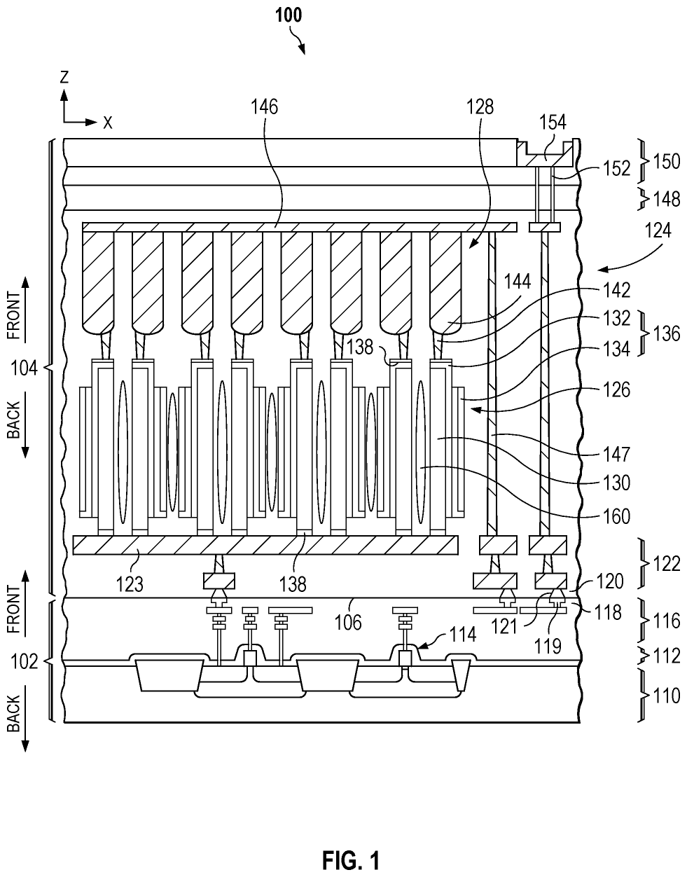

FIG. 1 illustrates a side view of a cross-section of an example 3D semiconductor device 100. The 3D semiconductor device 100 can be a 3D dynamic random-access memory (DRAM). It is understood that FIG. 1 is for illustrative purposes only and may not necessarily reflect the actual device structure (e.g., interconnections) in practice. In some implementations, the 3D semiconductor device 100 is a bonded chip including a first semiconductor structure 102 and a second semiconductor structure 104 stacked over the first semiconductor structure 102. The first and second semiconductor structures 102 and 104 can be jointed at bonding interface 106 therebetween.

As shown in FIG. 1, the first semiconductor structure 102 can include a substrate 110, which can include silicon (e.g., single crystalline silicon, c-Si), SiGe, GaAs, Ge, SOI, or any other suitable materials. The first semiconductor structure 102 can include peripheral circuits 112 on and/or in the substrate 110. In some implementations, the peripheral circuits 112 include a plurality of transistors 114 (e.g., planar transistors and/or 3D transistors). Trench isolations (e.g., shallow trench isolations (STIs)) and doped regions (e.g., wells, sources, and drains of transistors 114) can be formed on or in the substrate 110 as well. In some examples, the peripheral circuits 112 are formed using complementary metal-oxide-semiconductor (CMOS) technology, and the first semiconductor structure 102 can be also formed on a semiconductor die that can be referred to as a control die or a CMOS die 102.

In some implementations, the first semiconductor structure 102 further includes an interconnect layer 116 above the peripheral circuits 112 to transfer electrical signals to and from the peripheral circuits 112. The interconnect layer 116 can include a plurality of interconnects (also referred to herein as “contacts”), including lateral interconnect lines and VIA contacts. The interconnect layer 116 can further include one or more interlay dielectric (ILD) layers in which the interconnect lines and via contacts can form. That is, the interconnect layer 116 can include interconnect lines and via contacts in multiple ILD layers. In some implementations, peripheral circuits 112 are coupled to one another through the interconnects in the interconnect layer 116. The interconnects in interconnect layer 116 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

As shown in FIG. 1, the first semiconductor structure 102 has a front side and a back side, and the first semiconductor structure 102 can further include a bonding layer 118 at the back side at the bonding interface 106 and above the interconnect layer 116 and the peripheral circuits 112. The bonding layer 118 can include a plurality of bonding contacts 119 and dielectrics electrically isolating the bonding contacts 119. The bonding contacts 119 can include conductive materials, such as Cu. The remaining area of the bonding layer 118 can be formed with dielectric materials, such as silicon oxide. The bonding contacts 119 and surrounding dielectrics in the bonding layer 118 can be used for hybrid bonding. Similarly, as shown in FIG. 1, the second semiconductor structure 104 can also include a bonding layer 120 at the bonding interface 106 and above the bonding layer 118 of the first semiconductor structure 102. The bonding layer 120 can include a plurality of bonding contacts 121 and dielectrics electrically isolating the bonding contacts 121. The bonding contacts 121 can include conductive materials, such as Cu. The remaining area of the bonding layer 120 can be formed with dielectric materials, such as silicon oxide. The bonding contacts 121 and surrounding dielectrics in the bonding layer 120 can be used for hybrid bonding. The bonding contacts 121 can be in contact with the bonding contacts 119 at the bonding interface 106. In some implementations, the bonding layer 120 includes a dielectric layer opposing memory cells (e.g., DRAM cells) 124 with a bit line 123 positioned between the dielectric layer and the memory cells 124, as shown in FIG. 1. The dielectric layer can include the bonding interface 106 having the bonding contacts 121.

The second semiconductor structure 104 can be bonded on top of the first semiconductor structure 102 in a face-to-face manner at the bonding interface 106. In some implementations, the bonding interface 106 is disposed between the bonding layers 120 and 118 as a result of hybrid bonding (also known as “metal/dielectric hybrid bonding”), which is a direct bonding technology (e.g., forming bonding between surfaces without using intermediate layers, such as solder or adhesives) and can obtain metal-metal bonding and dielectric-dielectric bonding simultaneously. In some implementations, the bonding interface 106 is the place at which bonding layers 120 and 118 are met and bonded. In some examples, the bonding interface 106 can be a layer with a certain thickness that includes the top surface of the bonding layer 118 of the first semiconductor structure 102 and the bottom surface of the bonding layer 120 of the second semiconductor structure 104.

In some implementations, the second semiconductor structure 104 further includes an interconnect layer 122 including bit lines 123 above the bonding layer 120 to transfer electrical signals. The interconnect layer 122 can include a plurality of interconnects, such as mid end of line (MEOL) interconnects and back end of line (BEOL) interconnects. In some implementations, the interconnects in interconnect layer 122 also include local interconnects, such as the bit lines 123 and word line contacts (not shown). The interconnect layer 122 can further include one or more ILD layers in which the interconnect lines and via contacts can form. The interconnects in the interconnect layer 122 can include conductive materials including, but not limited to, W, Co, Cu, Al, doped silicon, silicides, or any combination thereof. The ILD layers can be formed with dielectric materials including, but not limited to, silicon oxide, silicon nitride, silicon oxynitride, low-k dielectrics, or any combination thereof.

In some implementations, the peripheral circuits 112 include a word line driver/row decoder coupled to the word line contacts in the interconnect layer 122 through the bonding contacts 121 and 119 in the bonding layers 120 and 118 and the interconnect layer 116. In some implementations, the peripheral circuits 112 include a bit line driver/column decoder coupled to the bit lines 123 and bit line contacts in the interconnect layer 122 through the bonding contacts 121 and 119 in the bonding layers 120 and 118 and the interconnect layer 116. In some implementations, the bit line 123 is a metal bit line, as opposed to semiconductor bit lines (e.g., doped silicon bit lines). For example, the bit line 123 may include W, Co, Cu, Al, or any other suitable metals having higher conductivities than doped silicon. In some implementations, the bit line contact is an ohmic contact as opposed to a Schottky contact.

In some implementations, e.g., as discussed with further details below, the bit line 123 is made of a composite conductive material that can be based on a metallic material (e.g., W, Co, Cu, Al) and a semiconductor material (e.g., Si). For example, the composite conductive material can include metal silicide, e.g., such as WSi, CoSi, CuSi, AlSi, or any other suitable metal silicides having higher conductivities than doped silicon.

In some implementations, the second semiconductor structure 104 includes a DRAM device in which memory cells are provided in the form of an array of DRAM cells 124 above the interconnect layer 122 and the bonding layer 120. That is, the interconnect layer 122 including the bit lines 123 can be disposed between bonding layer 120 and array of DRAM cells 124. A bit line 123 in the interconnect layer 122 can be coupled to a string of DRAM cells 124. In some implementations, the second semiconductor structure 104 is formed on a semiconductor die and can be referred to as array die 104.

In some implementations, a semiconductor device can include multiple array dies (e.g., the array die 104) and a CMOS die (e.g., the CMOS die 102). The multiple array dies and the CMOS die can be stacked and bonded together. The CMOS die can be respectively coupled to each of the multiple array dies, and can respectively drive each of the multiple array dies to operate in the similar manner as the semiconductor device. The semiconductor device can be any suitable device. In some examples, the semiconductor device includes at least a first wafer and a second wafer bonded face to face. The array die can be disposed with other array dies on the first wafer, and the CMOS die can be disposed with other CMOS dies on the second wafer. The first wafer and the second wafer can be bonded together, thus the array dies on the first wafer can be bonded with corresponding CMOS dies on the second wafer. In some examples, the semiconductor device is a chip with at least the array die and the CMOS die bonded together. In an example, the chip is diced from wafers that are bonded together. In another example, the semiconductor device is a semiconductor package that includes one or more semiconductor chips assembled on a package substrate.

Each DRAM cell 124 can include a vertical transistor 126 and a capacitor 128 coupled to the vertical transistor 126. DRAM cell 124 can be a 1T1C cell consisting of one transistor and one capacitor. It is understood that DRAM cell 124 may be of any suitable configurations, such as 2T1C cell, 3T1C cell, etc. The vertical transistor 126 can be a MOSFET used to switch a respective DRAM cell 124. In some implementations, the vertical transistor 126 includes a semiconductor body 130 (the active region in which a channel can form) extending vertically (in the z-direction), and a gate structure 136 in contact with one side of semiconductor body 130. In a single-gate vertical transistor, the semiconductor body 130 can have a cuboid shape or a cylinder shape, and the gate structure 136 can abut a single side of semiconductor body 130 in a plane view, e.g., as shown in FIG. 1. In some implementations, the vertical transistor 126 has a structure including two or more gates, e.g., a two-gates structure, a three-gates structure, or a gate all around (GAA) structure. In some implementations, the gate structure 136 includes a gate electrode 134 and a gate dielectric 132 laterally between the gate electrode 134 and the semiconductor body 130 in a bit line direction (e.g., in the x-direction). In some implementations, the gate dielectric 132 abuts one side of the semiconductor body 130, and the gate electrode 134 abuts the gate dielectric 132.

As shown in FIG. 1, in some implementations, the semiconductor body 130 has two ends (the upper end and lower end in FIG. 1) in the vertical direction (the z-direction), and at least one end (e.g., the lower end) extends beyond gate dielectric 132 in the vertical direction (the z-direction) into the ILD layers. In some implementations, one end (e.g., the upper end) of the semiconductor body 130 is flush with the respective end (e.g., the upper end) of the gate dielectric 132. In some implementations, both ends (the upper end and lower end) of the semiconductor body 130 extend beyond the gate electrode 134, respectively, in the vertical direction (the z-direction) into ILD layers. That is, the semiconductor body 130 can have a larger vertical dimension (e.g., the depth) than that of the gate electrode 134 (e.g., in the z-direction), and neither the upper end nor the lower end of semiconductor body 130 is flush with the respective end of the gate electrode 134. Thus, short circuits between the bit lines 123 and the word lines/gate electrodes 134 or between the word lines/gate electrodes 134 and the capacitors 128 can be avoided. The vertical transistor 126 can further include a source and a drain (both referred to as 138 as their locations may be interchangeable) disposed at the two ends (the upper end and lower end) of the semiconductor body 130, respectively, in the vertical direction (the z-direction). In some implementations, one of the source and drain 138 (e.g., at the upper end in FIG. 1) is coupled to the capacitor 128, and the other one of source and drain 138 (e.g., at the lower end in FIG. 1) is coupled to the bit line 123. That is, the vertical transistor 126 can have a first terminal in the positive z-direction and a second terminal opposite the first terminal in the negative z-direction, as shown in FIG. 1.

In some implementations, the semiconductor body 130 includes semiconductor materials, such as single crystalline silicon, polysilicon, amorphous silicon, Ge, any other semiconductor materials, or any combinations thereof. In one example, semiconductor body 130 may include single crystalline silicon. Source and drain 138 can be doped with N+ type dopants (e.g., Phosphorus (P) or Arsenic (As)) or P-type dopants (e.g., Boron (B) or Gallium (Ga)) at a desired doping level. In some implementations, a silicide layer, such as a metal silicide layer, is formed between source/drain 138 of the vertical transistor 126 and the bit line 123 as the bit line contact or between source/drain 138 of the vertical transistor 126 and the first electrode of the capacitor 128 as capacitor contact 142 to reduce the contact resistance. In some implementations, gate dielectric 132 includes dielectric materials, such as silicon oxide, silicon nitride, or high-k dielectrics including, but not limited to, Al2O3, HfO2, Ta2O5, ZrO2, TiO2, or any combination thereof. In some implementations, gate electrode 134 includes a conductive material including, but not limited to W, Co, Cu, Al, TiN, TaN, polysilicon, silicide, or any combination thereof. In some implementations, the gate electrode 134 includes multiple conductive layers, such as a W layer over a TiN layer. In one example, the gate structure 136 may be a “gate oxide/gate poly” gate in which the gate dielectric 132 includes silicon oxide and gate electrode 134 includes doped polysilicon. In another example, gate structure 136 may be an HKMG in which gate dielectric 132 includes a high-k dielectric and gate electrode 134 includes a metal.

As described above, since the gate electrode 134 may be part of a word line or extend in the word line direction (e.g., the y-direction) as a word line, the second semiconductor structure 104 of the 3D semiconductor device 100 can also include a plurality of word lines each extending in the word line direction (the y-direction). Each word line 134 can be coupled to a row of DRAM cells 124. That is, the bit line 123 and the word line 134 can extend in two perpendicular lateral directions, and the semiconductor body 130 of the vertical transistor 126 can extend in the vertical direction perpendicular to the two lateral directions in which the bit line 123 and the word line 134 extend. Word lines 134 are in contact with word line contacts (not shown). In some implementations, the word lines 134 include conductive materials including, but not limited to W, Co, Cu, Al, TiN, TaN, polysilicon, silicides, or any combination thereof. In some implementations, the word line 134 includes multiple conductive layers, such as a W layer over a TiN layer, as shown in FIG. 1.

In some implementations, as shown in FIG. 1, the vertical transistor 126 extends vertically through and contacts the word lines 134, and the source or drain 138 of vertical transistor 126 at the lower end thereof is in contact with the bit line 123 (or bit line contact if any). Accordingly, the word lines 134 and the bit lines 123 can be disposed in different planes in the vertical direction due to the vertical arrangement of vertical transistor 126, which simplifies the routing of the word lines 134 and the bit lines 123. In some implementations, the bit lines 123 are disposed vertically between the bonding layer 120 and the word lines 134, and the word lines 134 are disposed vertically between the bit lines 123 and the capacitors 128. The word lines 134 can be coupled to the peripheral circuits 112 in the first semiconductor structure 102 through word line contacts (not shown) in the interconnect layer 122, the bonding contacts 121 and 119 in the bonding layers 120 and 118, and the interconnects in the interconnect layer 116. Similarly, the bit lines 123 in the interconnect layer 122 can be coupled to the peripheral circuits 112 in the first semiconductor structure 102 through the bonding contacts 121 and 119 in the bonding layers 120 and 118 and the interconnects in the interconnect layer 116.

In some implementations, the vertical transistors 126 can be arranged in a mirror-symmetric manner to increase the density of DRAM cells 124 in the bit line direction (the x-direction). As shown in FIG. 1, two adjacent vertical transistors 126 in the bit line direction are mirror-symmetric to one another with respect to a trench isolation 160. That is, the second semiconductor structure 104 can include a plurality of trench isolations 160 each extending in the word line direction (the y-direction) in parallel with word lines 134 and disposed between semiconductor bodies 130 of two adjacent rows of the vertical transistors 126. In some implementations, the rows of vertical transistors 126 separated by the trench isolation 160 are mirror-symmetric to one another with respect to the trench isolation 160. The trench isolation 160 can be formed with dielectric materials including, but not limited to, silicon oxide, silicon nitride, silicon oxynitride, low-k dielectrics, or any combination thereof. It is understood that the trench isolation 160 may include an air gap each disposed laterally between adjacent semiconductor bodies 130. Air gaps may be formed due to the relatively small pitches of vertical transistors 126 in the bit line direction (e.g., the x-direction). On the other hand, the relatively large dielectric constant of air in air gaps (e.g., about 4 times of the dielectric constant of silicon oxide) can improve the insulation effect between vertical transistors 126 (and rows of DRAM cells 124) compared with some dielectrics (e.g., silicon oxide). Similarly, in some implementations, air gaps are formed laterally between word lines/gate electrodes 134 in the bit line direction as well, depending on the pitches of word lines/gate electrodes 134 in the bit line direction.

As shown in FIG. 1, in some implementations, a capacitor 128 includes a first electrode 144 above and coupled to the source or drain 138 of vertical transistor 126, e.g., the upper end of the semiconductor body 130, via a capacitor contact 142. In some implementations, the capacitor contact 142 is an ohmic contact, such as a metal silicide contact, as opposed to a Schottky contact. For example, the capacitor contact 142 may include metal silicides, such as WSi, CoSi, CuSi, AlSi, or any other suitable metal silicides having higher conductivities than doped silicon. The capacitor 128 can also include a capacitor dielectric above and in contact with the first electrode 144, and a second electrode above and in contact with the capacitor dielectric. That is, the capacitor 128 can be a vertical capacitor in which the electrodes and capacitor dielectric are stacked vertically (in the z-direction), and the capacitor dielectric can be sandwiched between the electrodes. In some implementations, each first electrode is coupled to source or drain 138 of a respective vertical transistor 126 in the same DRAM cell, while all second electrodes are coupled to a common plate 146 coupled to the ground, e.g., a common ground. The capacitor 128 can have a first end in the negative z-direction and a second end opposite the first end in the positive z-direction, as shown in FIG. 1. In some implementations, the first end of the capacitor 128 is coupled to the first terminal of the vertical transistor 126 via an ohmic contact (e.g., the capacitor contact 142 made of a metal silicide material). As shown in FIG. 1, the second semiconductor structure 104 can further include a capacitor contact 147 (e.g., a conductor) in contact with a common plate 146 for coupling the capacitors 128 to the peripheral circuits 112 or to the ground directly. In some implementations, the capacitor contact 147 (e.g., a conductor) extends in the z-direction from the dielectric layer of the bonding layer 120 to couple to the second end of the capacitor 128 via the common plate 146, as shown in FIG. 1. In some implementation, the ILD layer in which the capacitors 128 are formed has the same dielectric material as the two ILD layers into which the semiconductor body 130 extends, such as silicon oxide.

It is understood that the structure and configuration of a capacitor 128 are not limited to the example in FIG. 1 and may include any suitable structure and configuration, such as a planar capacitor, a stack capacitor, a multi-fins capacitor, a cylinder capacitor, a trench capacitor, or a substrate-plate capacitor. In some implementations, the capacitor dielectric includes dielectric materials, such as silicon oxide, silicon nitride, or high-k dielectrics including, but not limited to, Al2O3, HfO2, Ta2O5, ZrO2, TiO2, or any combination thereof. It is understood that in some examples, a capacitor 128 may be a ferroelectric capacitor used in a FRAM cell, and the capacitor dielectric may be replaced by a ferroelectric layer having ferroelectric materials, such as PZT or SBT. In some implementations, the electrodes include conductive materials including, but not limited to W, Co, Cu, Al, TiN, TaN, polysilicon, silicides, or any combination thereof.

As shown in FIG. 1, vertical transistor 126 extends vertically through and contacts the word lines 134, source or drain 138 of vertical transistor 126 at the lower end thereof is in contact with the bit line 123, and source or drain 138 of vertical transistor 126 at the upper end thereof is coupled to the capacitor 128. That is, the bit line 123 and the capacitor 128 can be disposed in different planes in the vertical direction and coupled to opposite ends of vertical transistor 126 of DRAM cell 124 in the vertical direction due to the vertical arrangement of vertical transistor 126. In some implementations, the bit line 123 and the capacitor 128 are disposed on opposite sides of the vertical transistor 126 in the vertical direction, which simplifies the routing of the bit lines 123 and reduces the coupling capacitance between the bit lines 123 and the capacitors 128 compared with DRAM cells in which the bit lines and capacitors are disposed on the same side of the planar transistors.

As shown in FIG. 1, in some implementations, the vertical transistors 126 are disposed vertically between the capacitors 128 and the bonding interface 106. That is, the vertical transistors 126 can be arranged closer to the peripheral circuits 112 of the first semiconductor structure 102 and the bonding interface 106 than the capacitors 128. Since the bit lines 123 and the capacitors 128 are coupled to opposite ends of the vertical transistors 126, the bit lines 123 (as part of the interconnect layer 122) are disposed vertically between the vertical transistors 126 and the bonding interface 106 As a result, the interconnect layer 122 including bit lines 123 can be arranged close to the bonding interface 106 to reduce the interconnect routing distance and complexity.

In some implementations, second semiconductor structure 104 further includes a substrate 148 disposed above the DRAM cells 124. As described below with respect to the fabrication process, the substrate 148 can be part of a carrier wafer. It is understood that in some examples, the substrate 148 may not be included in the second semiconductor structure 104.

As shown in FIG. 1, the second semiconductor structure 104 can further include a pad-out interconnect layer 150 above the substrate 148 and the DRAM cells 124. The pad-out interconnect layer 150 can include interconnects, e.g., contact pads 154, in one or more ILD layers. The pad-out interconnect layer 150 and the interconnect layer 122 can be formed on opposite sides of the DRAM cells 124. The capacitors 128 can be disposed vertically between the vertical transistors 126 and the pad-out interconnect layer 150. In some implementations, the interconnects in pad-out interconnect layer 150 can transfer electrical signals between the 3D semiconductor device 100 and outside circuits, e.g., for pad-out purposes.

In some implementations, the second semiconductor structure 104 further includes one or more contacts 152 extending through the substrate 148 and part of the pad-out interconnect layer 150 to couple the pad-out interconnect layer 150 to the DRAM cells 124 and the interconnect layer 122. As a result, the peripheral circuits 112 can be coupled to the DRAM cells 124 through the interconnect layers 116 and 122 as well as the bonding layers 120 and 118, and the peripheral circuits 112 and the DRAM cells 124 can be coupled to outside circuits through contacts 152 and pad-out interconnect layer 150. Contact pads 154 and contacts 152 can include conductive materials including, but not limited to, W, Co, Cu, Al, silicides, or any combination thereof. In one example, the contact pad 154 may include Al, and the contact 152 may include W. In some implementations, the contact 152 includes a via surrounded by a dielectric spacer (e.g., having silicon oxide) to electrically separate the via from substrate 148. Depending on the thickness of substrate 148, contact 152 can be an ILV having a depth in the submicron level (e.g., between 10 nm and 1 μm), or a TSV having a depth in the micron- or tens micron-level (e.g., between 1 μm and 100 μm).

Although not shown, it is understood that the pad-out of 3D memory devices is not limited to from the second semiconductor structure 104 having DRAM cells 124 as shown in FIG. 1 and may be from the first semiconductor structure 102 having peripheral circuit 112. Although not shown, it is also understood that the air gaps between word lines 134 and/or between semiconductor bodies 130 may be partially or fully filled with dielectrics. Although not shown, it is further understood that more than one array of DRAM cells 124 may be stacked over one another to vertically scale up the number of DRAM cells 124.

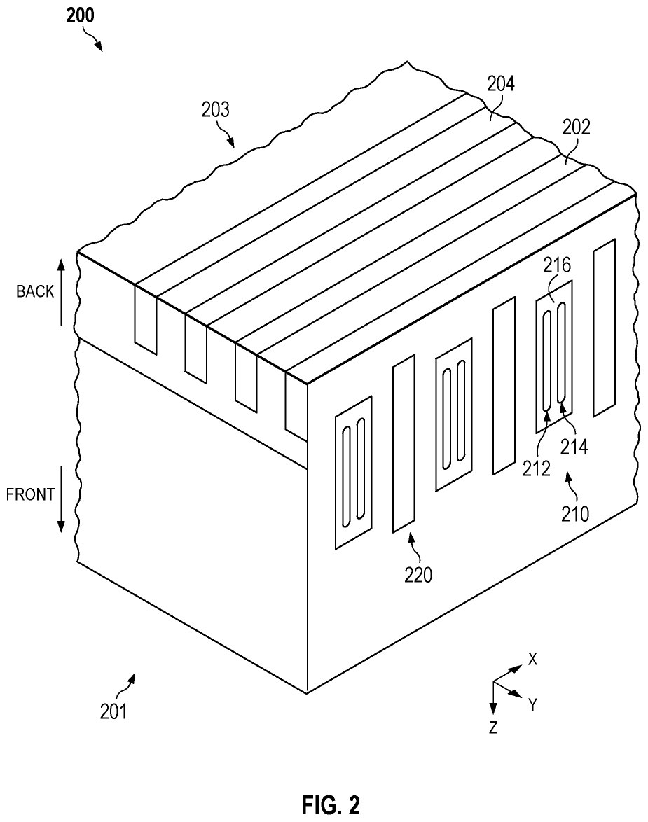

FIG. 2 shows a perspective view of an example 3D semiconductor device 200. The 3D semiconductor device 200 can be the 3D semiconductor device 100 of FIG. 1 or a structure at an intermediate fabrication process of the 3D semiconductor device 100 of FIG. 1.

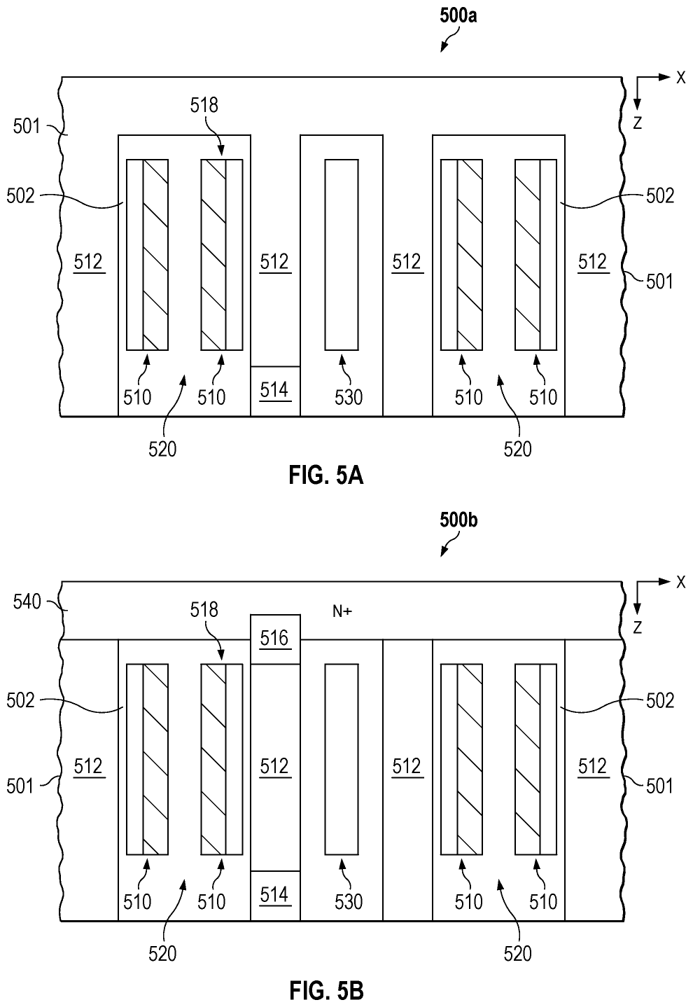

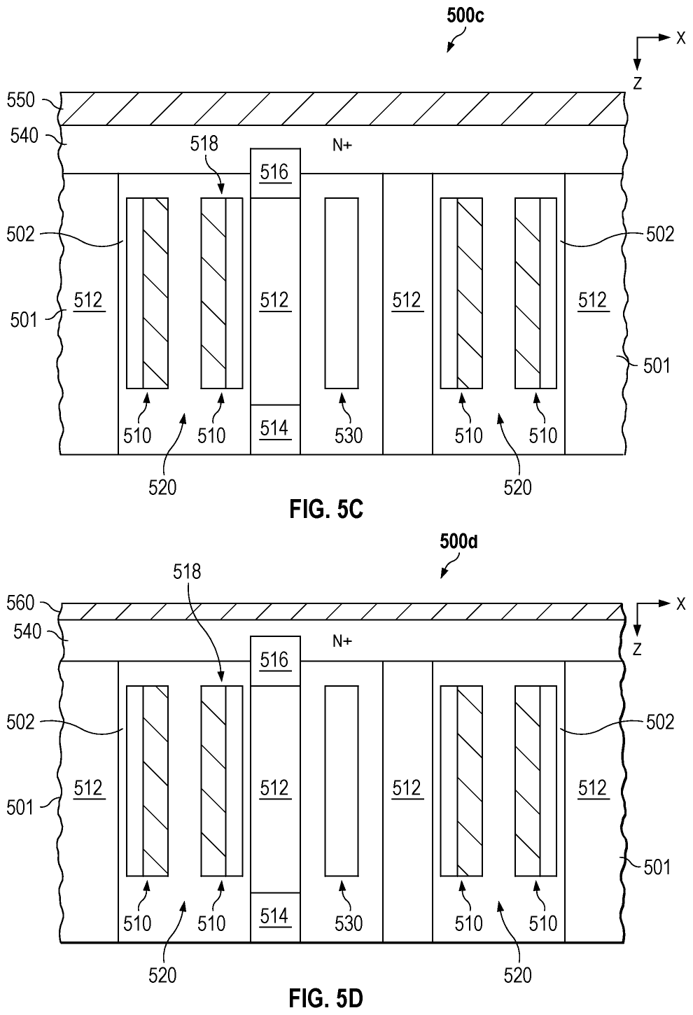

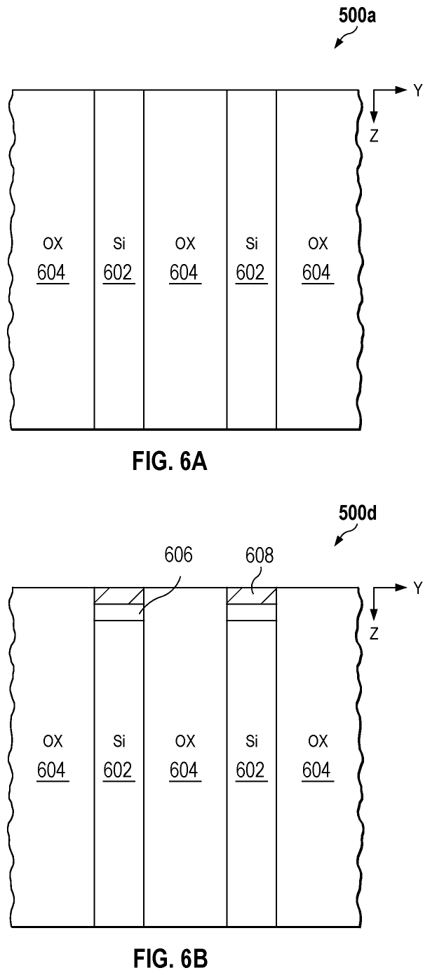

As shown in FIG. 2, the 3D semiconductor device 200 has a front side 201 and a back side 203 along a vertical direction (the Z direction). The 3D semiconductor device 200 includes a plurality of bit lines 202 separated by an isolating material 204 (e.g., oxide) on the back side 203. The bit line 202 can be similar to, or same as, the bit line 123 of FIG. 1. The bit lines 202 can be separated along the Y direction and extend along the X direction. As shown in FIG. 2, the bit lines 202 have a depth along the vertical direction (Z direction). As discussed with further details below, e.g., in FIGS. 5A-5D and 6A-6B, the bit lines 202 can be formed by depositing a layer of a metallic material (e.g., Ni) on a plurality of alternating stripes of semiconductor material (e.g., Si) and isolating material 204 (e.g., oxide), and forming a composite conductive material (e.g., silicide such as NiSi) based on the metallic material and the semiconductor material in the corresponding stripes of the semiconductor material. Thus, the bit lines 202 can be self-aligned.

The 3D semiconductor device 200 can include strings of memory cells on the front side 201. Each string of memory cells can be coupled to a corresponding bit line 202. A memory cell can be similar to, or same as, the DRAM cell 124 of FIG. 1. The memory cell can include a vertical transistor (e.g., the vertical transistor 126 of FIG. 1) and a capacitor (e.g., the capacitor 128 of FIG. 1) coupled to the vertical transistor. In some implementations, gate structures (e.g., the gate structure 136 of FIG. 1) of two vertical transistors 212, 214 can be formed in a trench structure 210 and separated by an isolating material 216 (e.g., oxide) in the trench structure 210. Adjacent trench structures 210 (or adjacent vertical transistors in the adjacent trench structures 210) can be separated by an isolating region 220 (e.g., the trench isolation 160 of FIG. 1) along the X direction.

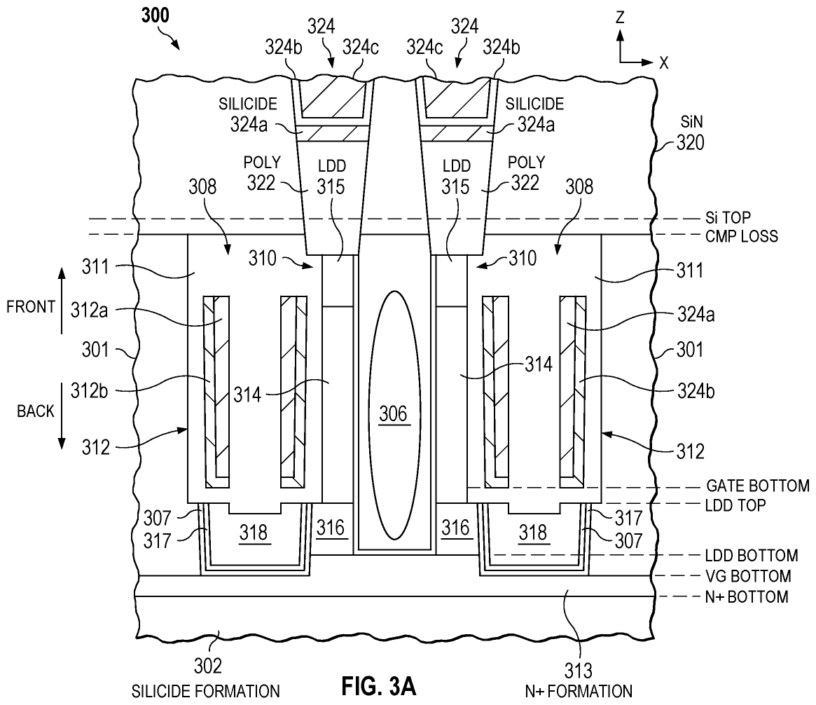

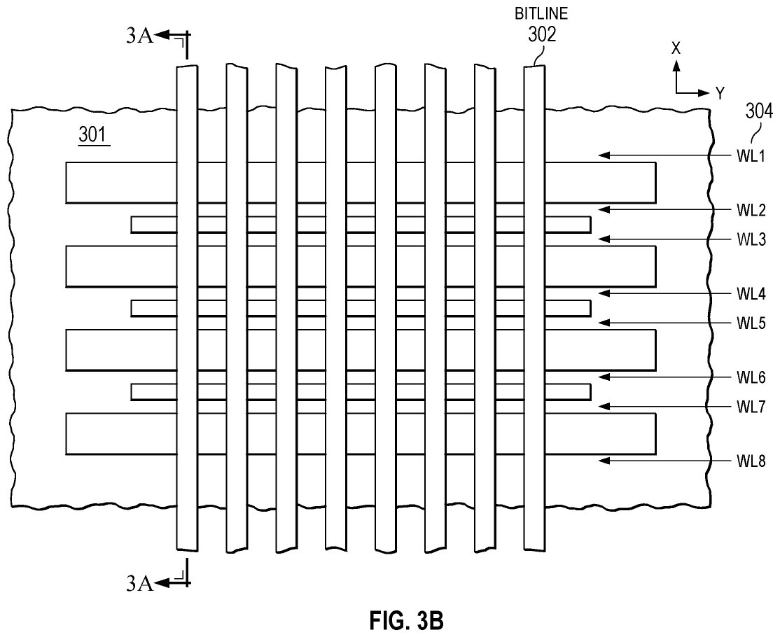

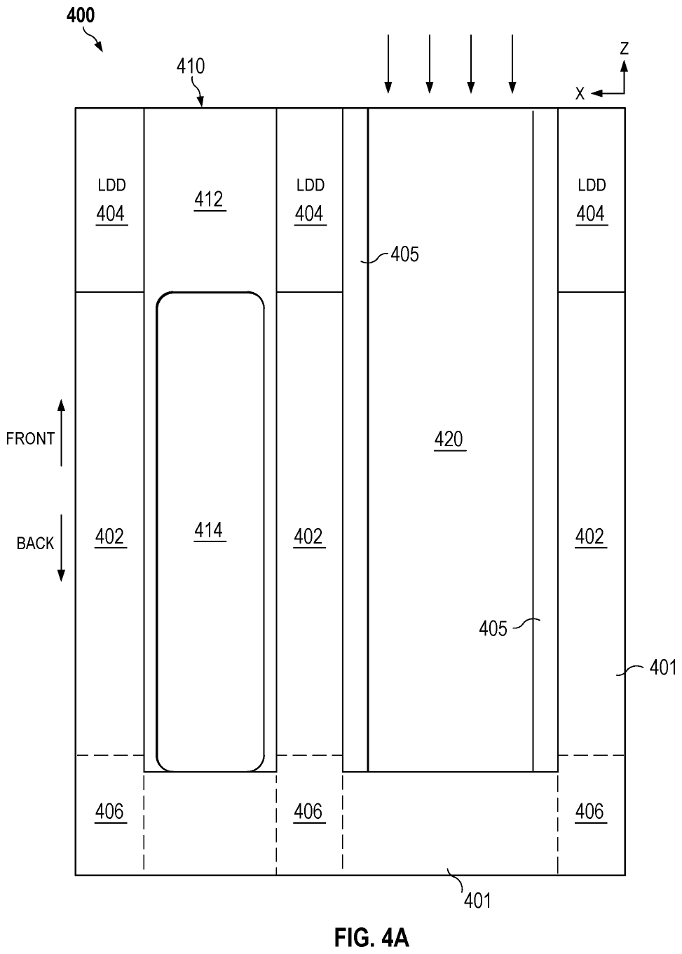

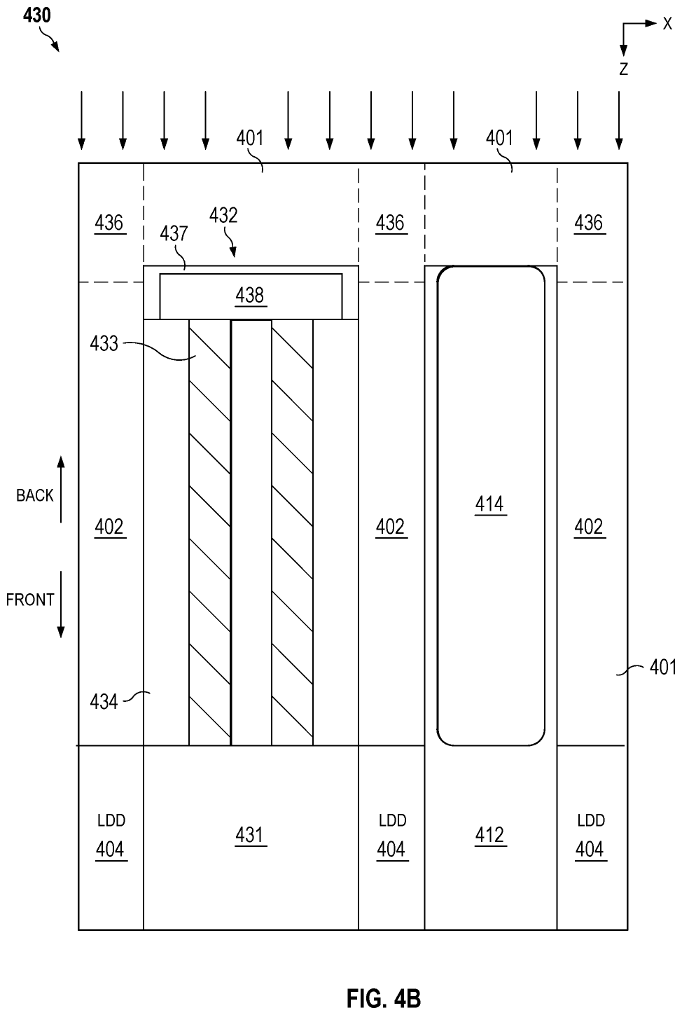

FIG. 3A illustrates a cross-sectional view of an example 3D semiconductor device 300 including vertical transistors and bit lines (e.g., in the XZ plane). FIG. 3B illustrates a top view of the example 3D semiconductor device 300 of FIG. 3A (e.g., in the XY plane). The 3D semiconductor device 300 can be the 3D semiconductor device 200 of FIG. 2 or the 3D semiconductor device 100 of FIG. 1 or a structure at an intermediate fabrication process of the 3D semiconductor device 100 of FIG. 1. The 3D semiconductor device 300 can be formed by methods and/or processes described with further details in FIGS. 4A-4B, 5A-5D, 6A-6B, and/or 7A-7B.

As illustrated in FIG. 3B, the 3D semiconductor device 300 includes a plurality of bit lines 302 extending along X direction and a plurality of word lines (WL1, W2, . . . , WL8, . . . ) 304 extending along Y direction. Adjacent bit lines 302 are separated by an isolating material (e.g., oxide such as 204 of FIG. 2) along Y direction, and adjacent word lines 304 are separated by an isolating region 306 along X direction. The bit line 302 can be similar to, or same as, the bit line 123 of FIG. 1 or the bit line 202 of FIG. 2. The isolating region 306 can be similar to, or same as, the trench isolation 160 of FIG. 1 or the isolating region 220 of FIG. 2. The isolating region 306 can be formed with dielectric materials including, but not limited to, silicon oxide, silicon nitride, silicon oxynitride, low-k dielectrics, or any combination thereof. It is understood that the isolating region 306 may include an air gap disposed laterally between adjacent semiconductor bodies 314 (e.g., along X direction).

The 3D semiconductor device 300 has a semiconductor substrate 301 that includes a semiconductor material (e.g., silicon). An array of memory cells (e.g., the memory cells 124 of FIG. 1) can be formed in the semiconductor substrate 301. Each memory cell can be a DRAM memory cell including a vertical transistor 310 (e.g., the vertical transistor 126 of FIG. 1 or the vertical transistor 212 or 214 of FIG. 2) and a capacitor (e.g., the capacitor 128 of FIG. 1) coupled to the vertical transistor 310. The vertical transistor 310 can include a gate electrode (or a gate terminal) 312, a semiconductor body 314, a first terminal 315 and a second terminal 316 formed on opposite ends of the semiconductor body 314 along a vertical direction (e.g., Z direction). One of the first terminal 315 and the second terminal 316 can be a source terminal and the other of the first terminal 315 and the second terminal 316 can be a drain terminal. The first terminal 315 and the second terminal 316 can be similar to, or same as, the terminals 138 of FIG. 1.

The semiconductor body 314 can be similar to, or same as, the semiconductor body 130 of FIG. 1. The semiconductor body 314 can include a semiconductor material, such as single crystalline silicon, polysilicon, amorphous silicon, Ge, any other semiconductor materials, or any combinations thereof. In one example, the semiconductor body 314 may include single crystalline silicon. As discussed with further details below, each of the first terminal 315 and the second terminal 316 can be formed by implanting N+ type ions (e.g., P or As) or P-type ions (e.g., B or Ga) at a desired doping level into an end of the semiconductor body 314. In one example, the first terminal 315 represents a drain terminal (e.g., a lightly doped drain—LDD), and the second terminal 316 represents a source terminal. In another example, the first terminal 315 represents a source terminal, and the second terminal 316 represents a drain terminal.

The gate electrode 312 can include one or more conductive layers, such as a W layer 312a over a TiN layer 312b, e.g., as shown in FIG. 3A. An isolating material 311 can be formed as a gate dielectric (e.g., the gate dielectric 132 of FIG. 1) between the semiconductor body 314 and the gate electrode 312. The gate electrode 312 may be part of a word line 304 or extend in the word line direction (e.g., the Y-direction) as a word line 304. The gate electrode 312 and the gate dielectric can form a gate structure (e.g., the gate structure 136 of FIG. 1).

In some implementations, the 3D semiconductor device 300 includes trench structures 308 (e.g., the trench structure 210 of FIG. 2) that are separated by the isolating region 306. Gate electrodes 312 of a pair of vertical transistors 310 can be formed in the trench structure 308 and separated by the isolating material 311. Bottom ends of the gate electrodes 312 of the vertical transistors 310 in the trench structure 308 can be separated by one or more isolating layers 307 (e.g., oxide), 317 (e.g., SiN), and 318 (e.g., oxide). The gate electrodes 312 can be separated and isolated from the first terminal 315 and the second terminal 316, e.g., by the isolating material 311. For example, as illustrated in FIG. 3A, along the Z direction, a bottom of the gate electrode 312 is higher than a top surface of the second terminal 316, and a bottom of the second terminal 316 can be higher than a bottom of the trench structure 308.

The first terminal 315 of the vertical transistor 310 can be coupled to a first electrode 324 (e.g., the first electrode 144 of FIG. 1) of the capacitor through a capacitor contact 322 (e.g., the capacitor contact 142 of FIG. 1). The capacitor contact 322 can include a VIA contact including a conductive material (e.g., polysilicon). The first electrode 324 can include one or more conducive layers, e.g., a metal silicide 324a in contact with the capacitor contact 322, an intermediate layer 324b (e.g., TiN layer), and a metallic layer 324c (e.g., W layer). A dielectric layer 320 (e.g., including SiN) can be formed on top of the semiconductor substrate 301. The capacitor contacts 322 can be formed at least partially in the dielectric layer 320, and can extend into the trench structure 308 to be in contact with the first terminal 315 of the vertical transistor 310.

In some implementations, the second terminal 316 of the vertical transistor 310 is coupled to the bit line 302, e.g., through an intermediate region 313. The intermediate region 313 can be between the bottoms of the second terminals 316 of the vertical transistors 310 and the bit line 302. The intermediate region 313 can be also between the bottoms of the trench structures 308 and the bit line 302. As discussed with further details below, e.g., FIGS. 5B-5C, the intermediate region 313 can be formed by implanting N+ type ions (e.g., P or As) into a back side of the semiconductor substrate 301. Ions implanted in the semiconductor substrate 301 can be referred to as dopants. The intermediate region 313 can have a higher dopant concentration that the second terminals 316 of the vertical transistors 310.

As discussed with further details below, e.g., FIGS. 5D and 6B, the bit lines 302 can be formed by depositing a layer of a metallic material (e.g., Ni) on the intermediate region 313 (e.g., alternating stripes of semiconductor material such as Si with implanted dopants and isolating material such as oxide) and then forming a composite conductive material (e.g., NiSi) based on the metallic material and the semiconductor material with the implanted dopants in the corresponding stripes of semiconductor material. In contrast, the metallic material does not react with the isolating material (e.g., oxide). Thus, the metallic material can be easily removed from surfaces of the stripes of the isolating material during an etching process (e.g., wet etching), and the composite conductive material in the corresponding stripes of semiconductive material can remain unchanged during the etching process and can form self-aligned bit lines. The composite conductive material can be silicide, e.g., metallic silicide.

FIG. 4A illustrates an example structure 400 showing forming a terminal of a vertical transistor by implanting N+ type ions from a front side of a semiconductor substrate 401. The vertical transistor can be similar to, or same as, the vertical transistor 126 of FIG. 1, the vertical transistor 212, 214 of FIG. 2, or the vertical transistor 310 of FIG. 3A.

The structure 400 includes a trench 420 for forming gate structures for vertical transistors. A gate structure can be similar to, or same as, the gate structure 136 of FIG. 1. The gate structure includes a gate electrode (e.g., the gate electrode 134 of FIG. 1 or the gate electrode 312 of FIG. 3A) and a gate dielectric (e.g., the gate dielectric 132 of FIG. 1) between the gate electrode and a semiconductor body 402 (e.g., the semiconductor body 130 of FIG. 1 or 314 of FIG. 3A) of the vertical transistor. The structure 400 includes a dielectric layer 405 (e.g., oxide) on an inner surface of the trench 420, which can be used for forming the gate dielectric of the gate structure of the vertical transistor. Moreover, the dielectric layer 405 can protect the semiconductor body 402 from N+ type ions in a later process step of implanting the N+ type ions from an opening of the trench 420 to a bottom of the trench 420.

The structure 400 can include an isolating region 410 between adjacent trenches 420 or adjacent semiconductor bodies 402 of vertical transistors. The isolating region 410 can be similar to, or same as, the trench isolation 160 of FIG. 1, the isolating region 220 of FIG. 2, or the isolating region 306 of FIG. 3A. The isolating region 410 can be formed with a dielectric material 412 enclosing an air gap 414 disposed laterally between the adjacent semiconductor bodies 402 (e.g., along X direction).

In the structure 400, a first terminal 404 (e.g., the first terminal 315 of FIG. 3A) of the vertical transistor is formed on a first end (e.g., a top end) of the semiconductor body 402 of the vertical transistor at a front side of the semiconductor substrate 401, e.g., by implanting N+ type ions into a region for the first terminal 404 from the front side of the semiconductor substrate 401. The first terminal 404 can be LDD.

To form a second terminal 406 (e.g., the second terminal 316 of FIG. 3A) on a second end (e.g., a bottom end) of the semiconductor body 402 of the vertical transistor, e.g., as shown in FIG. 4A, N+ type ions can be implanted from the opening of the trench 420 at the front side of the semiconductor substrate 401 to the bottom of the trench 420. The implanted ions can diffuse to a region of the second terminal 406 to form the second terminal 406 of the vertical transistor. One of the first terminal 404 and the second terminal 406 is a source terminal, and the other one of the first terminal 404 and the second terminal 406 is a drain terminal. In one example, a width of the opening of the trench 420 is about tens of nm, e.g., 40 nm to 50 nm.

FIG. 4B illustrates another example structure 430 showing forming a terminal of a vertical transistor by implanting N+ type ions from a back side of a semiconductor substrate 401. The vertical transistor can be similar to, or same as, the vertical transistor 126 of FIG. 1, the vertical transistor 212, 214 of FIG. 2, or the vertical transistor 310 of FIG. 3A.

Before forming a second terminal 436 (e.g., the second terminal 316 of FIG. 3A) of the vertical transistor, a first terminal 404 (e.g., the first terminal 315 of FIG. 3A) and/or a gate structure 432 (e.g., the gate structure 136 of FIG. 1) of the vertical transistor can be first formed. The gate structure 432 can include a gate electrode 433 and a gate dielectric 434 (e.g., the gate dielectric 132 of FIG. 1) coupled between the gate electrode 433 (e.g., the gate electrode 134 of FIG. 1 or the gate electrode 312 of FIG. 3A) and the semiconductor body 402. Adjacent gate structures 432 in a same trench can be isolated by an isolating material 431 (e.g., the isolating material 216 of FIG. 2 or 311 of FIG. 3A), and the gate structure 432 in the same trench can be covered by the isolating material 431. The gate structures 432 in the same trench can be separated by one or more isolating layers (e.g., a SiN layer 437 and an oxide layer 438) on a bottom of the trench.

Different from that in FIG. 4A, to form the second terminal 436 (e.g., the second terminal 316 of FIG. 3A) of the vertical transistor, in FIG. 4B, the N+ type ions (e.g., P) are implanted from the back side of the semiconductor substrate 401. The structure 430 can be flipped over and the semiconductor substrate 401 can be thinned (e.g., by chemical-mechanical polishing-CMP) from the back side to a thickness, e.g., about 100 nm. Then the N+ type ions can be directly implanted in the back side of the semiconductor substrate 401 to form the second terminals 436 at bottom ends of the semiconductor bodies 402, which can faster and easier than forming the second terminals 406 in FIG. 4A. Moreover, as the second terminals 436 are formed by direct implantation instead of diffusion, the second terminals 436 can have more uniform dopant concentrations than the second terminals 406 in FIG. 4A. Further, as the N+ type ions are implanted in a whole region of the back side of the semiconductor substrate 401, the process window is much greater than the opening of the trench 420 of FIG. 4A for implanting from the front side of the semiconductor substrate 401.

In some implementations, before implanting the N+ type ions, Germanium (Ge) pre-amorphization implantation (Ge PAI) is performed for low thermal activation. In some examples, semiconductor ions (e.g., Ge ions) are implanted with a depth (e.g., in a range of 20 to 40 nm), and then N+ type ions (e.g., P ions) are implanted, and the structure is activated at a low temperature, e.g., 500° C. to 600° C., which is lower than a nominal temperature, e.g., 900° C.

FIGS. 5A-5D show cross-sectional views (in XZ plane) of structures of a 3D semiconductor device at various stages of a fabrication process. FIGS. 6A-6B show cross-sectional views (in YZ plane) of some of the structures of the 3D semiconductor device to further illustrate the fabrication process. The 3D semiconductor device can be the 3D semiconductor device 300 of FIGS. 3A-3B, the 3D semiconductor device 200 of FIG. 2, the 3D semiconductor device 100 of FIG. 1, or a structure at an intermediate fabrication process of the 3D semiconductor device 100 of FIG. 1.

The 3D semiconductor device includes vertical transistors 510 (e.g., the vertical transistor 126 of FIG. 1, the vertical transistor 212, 214 of FIG. 2, or the vertical transistor 310 of FIG. 3A) formed in semiconductor substrate 501. The vertical transistors 510 extend along a vertical direction (e.g., Z direction). As noted above, a vertical transistor 510 can include a semiconductor body 512 (e.g., the semiconductor body 130 of FIG. 1, 314 of FIG. 3A, or 402 of FIG. 4A or 4B), first terminal 514 (e.g., the first terminal 315 of FIG. 3A, or 404 of FIG. 4A or 4B) and second terminal 516 (e.g., the second terminal 316 of FIG. 3A or 436 of FIG. 4B) on opposite ends of the semiconductor body 512, a gate structure 518 (e.g., the gate structure 136 of FIG. 1 or 432 of FIG. 4B) coupled to the semiconductor body 512. For illustration purposes, in FIGS. 5A-5D, components in the structures are simplified, and only one vertical transistor 510 is shown with details.

In some implementations, the 3D semiconductor device includes trench structures 520 (e.g., the trench structure 210 of FIG. 2 or 308 of FIG. 3A) that are separated by an isolating region 530 along a lateral direction (e.g., X direction). In some implementations, the isolating region 530 includes an air gap, e.g., the isolating region 160 of FIG. 1, 220 of FIG. 2, 306 of FIG. 3A, or 410 of FIG. 4A or 4B. In some implementations, the isolating region 530 includes a conducting structure (e.g., including a metallic material such as W). The conducting structure can be coupled to a low voltage (e.g., a negative voltage), which can reduce or eliminate a backside coupling effect or a Row hammer effect. In some cases, the conducting structure can be in contact with at least one of the adjacent semiconductor bodies 512, which can reduce or eliminate a floating body effect. Gate structures 518 of a pair of vertical transistors 510 can be formed in the trench structure 520 and separated by an isolating material 502 (e.g., oxide).

FIG. 5A shows a structure 500a that is similar to, or same as, the structure 430 of FIG. 4B. The structure 500a can include the first terminal 514 and the gate structure 518, e.g., formed from a front side of the semiconductor substrate 501. As shown in FIG. 5A, a back side of the structure 500a is faced up for subsequent ion implantation, e.g., to form the second terminal 516 of the vertical transistor 510. So the structure 500a may include uncompleted vertical transistors 510. The structure 500a can have a thinned semiconductor substrate on the back side, e.g., with a thickness of about 100 nm.

FIG. 6A shows a cross-sectional view of the back side of the structure 500a. As shown in FIG. 6A, alternating stripes of the semiconductor material (e.g., Si) 602 and the isolating material (e.g., oxide) 604 are formed along Y direction. In some implementations, the stripes of the isolating material 604 are formed by etching the semiconductor substrate 501 to form trenches and filling the isolating material 604 in the trenches from the front side of the semiconductor substrate 501. The semiconductor substrate 501 can be thinned (e.g., by CMP) from the back side to expose the stripes of the semiconductor material 602 and the isolating material 604. The stripes of the semiconductor material 602 and the isolating material 604 can extend into the semiconductor substrate 501 with a thickness, e.g., about 100 nm.

FIG. 5B shows a structure 500b after N+ type ions (e.g., P ions) are implanted into the semiconductor substrate 501 from the back side of the structure 500a. A region 540 of the semiconductor substrate with implanted ions can be similar to, or same as, the intermediate region 313 of FIG. 3A. In some implementations, the region 540 may extend to an end of the semiconductor body 512, e.g., as illustrated in FIG. 3A. The second terminal 516 can be formed at the end of the semiconductor body 512. Note that, as shown in FIG. 6A, the back side of the structure 500a includes the alternating stripes of the semiconductor material 602 and the isolating material 604. The N+ type ions can be implanted into the stripes of the semiconductor material 602, but not into the stripes of the isolating material 604.

In some implementations, before implanting the N+ type ions, semiconductor ions are first implanted, e.g., using Ge pre-amorphization implantation (Ge PAI), for low thermal activation. In some examples, Ge ions are implanted with a depth (e.g., in a range of 20 to 40 nm), and then the N+ type ions (e.g., P ions) are implanted, and the structure 500b can be then activated at a low temperature, e.g., in a range of 500° C. to 600° C. The temperature can be lower than a nominal temperature (e.g., about 900° C.) for activating the N+ type ions without implanting Ge ions.

FIG. 5C shows a structure 500c after a metallic layer 550 is formed on a surface of the back side of the structure 500b. The metallic layer 500 can cover both the stripes of the semiconductor material 602 (e.g., the region 540) and the stripes of the isolating material 604. The metallic layer 550 can include a metallic material, e.g., Ni.

FIG. 5D shows a structure 500d after performing an annealing process on the structure 500c. The metallic material of the metallic layer 550 and the semiconductor material of the semiconductor substrate 501 (e.g., the stripes of the semiconductor material 602) can react during the annealing process to form a composite conductive material 560, e.g., silicide. In some examples, the metallic material includes Ni, and the semiconductor material includes Si, and the composite conductive material includes NiSi.

After the annealing process, a residue of the metallic material of the metallic layer 550 can be removed from the back side of the semiconductor substrate 501, e.g., by etching such as wet etching. As the metallic material of the metallic layer 550 does not react with the stripes of the isolating material 604, the metallic material on the stripes of the isolating material 604 can be removed away, e.g., as shown in FIG. 6B. In contrast, a layer 608 of the composite conductive material 560 is formed as a bit line (e.g., the bit line 123 of FIG. 1, 202 of FIG. 2, or 302 of FIGS. 3A-3B) on a top of the stripes of the semiconductor material 602. The layer 608 of the composite conductive material 560 can be formed on top of a layer 606 of the semiconductor material 602 with implanted N+ type dopants in the region 540. In such a way, self-aligned bit lines are formed on the back side of the semiconductor substrate 501.

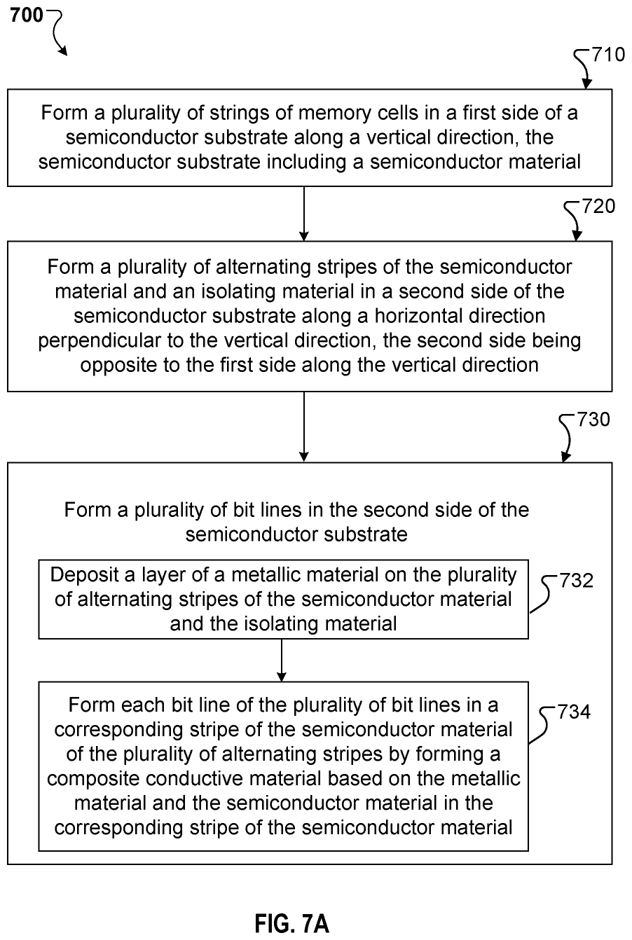

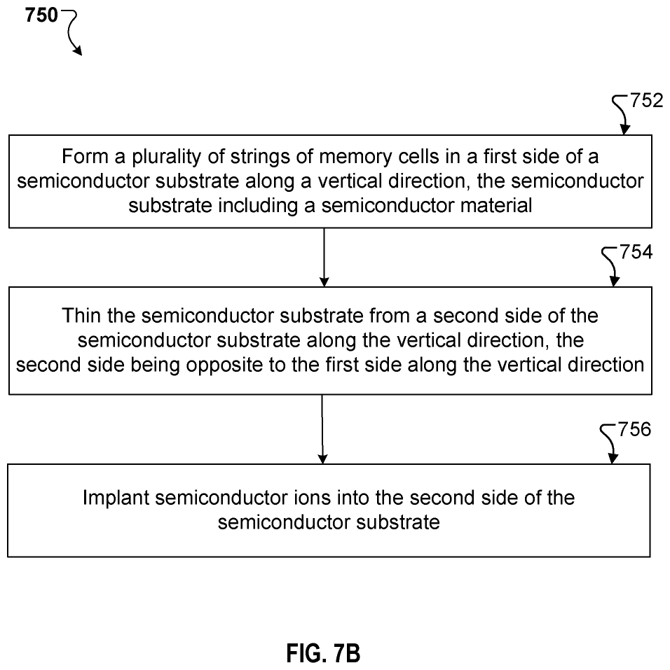

FIG. 7A is a flow chart of an example process 700 of forming a semiconductor device. The semiconductor device can be the 3D semiconductor device 300 of FIGS. 3A-3B, the 3D semiconductor device 200 of FIG. 2, the 3D semiconductor device 100 of FIG. 1, a structure at an intermediate fabrication process of the 3D semiconductor device 100 of FIG. 1, or the structure 500d of FIG. 5D. The process 700 can be described in view of FIGS. 5A-5D and FIGS. 6A-6B. The process 700 includes operations (or steps) that can be performed with any suitable order and/or any combination.

At operation 710, a plurality of strings of memory cells is formed in a first side of a semiconductor substrate along a vertical direction. The semiconductor substrate includes a semiconductor material (e.g., Si). The semiconductor substrate can be similar to, or same as, the semiconductor substrate for forming the first semiconductor substrate 104 of FIG. 1, the semiconductor substrate 301 of FIGS. 3A-3B, the semiconductor substrate 401 of FIGS. 4A-4B, or the semiconductor substrate 501 of FIG. 5A. The vertical direction can be Z direction. The first side of the semiconductor substrate can be a front side of the semiconductor substrate. The memory cells can be the memory cells 124 of FIG. 1, e.g., DRAM memory cells.

A memory cell can include a vertical transistor (e.g., the vertical transistor 126 of FIG. 1, the vertical transistor 212, 214 of FIG. 2, the vertical transistor 310 of FIG. 3A, or the vertical transistor 510 of FIGS. 5A-5D). In some implementations, e.g., as illustrated in FIG. 1, 3A, 4B, or 5A-5D, the vertical transistor includes a semiconductor body (e.g., the semiconductor body 130 of FIG. 1, 314 of FIG. 3A, 402 of FIG. 4B, or 512 of FIGS. 5A-5D), first and second terminals (e.g., the terminals 138 of FIG. 1, the terminals 315, 316 of FIG. 3, the terminals 404 and 436 of FIG. 4B, or the terminals 514, 516 of FIGS. 5B-5D) at opposite ends of the semiconductor body, and a gate structure (e.g., the gate structure 136 of FIG. 1, 432 of FIG. 4B, or 518 of FIGS. 5A-5D) coupled to the semiconductor body. The gate structure can include a vertical gate electrode (the gate electrode 134 of FIG. 1, 312 of FIG. 3A, or 433 of FIG. 4B) and a gate dielectric (e.g., the gate dielectric 132 of FIG. 1, 311 of FIG. 3A, or 434 of FIG. 4B) coupled between the vertical gate electrode and the semiconductor body.

In some implementations, forming the plurality of strings of memory cells includes: forming gate terminals (e.g., the vertical gate electrodes) of a pair of independent vertical transistors in a same trench (e.g., the trench 420 of FIG. 4A) along the vertical direction. The gate terminals can be separated by an isolating material (e.g., oxide) along a lateral direction (e.g., X direction) perpendicular to the vertical direction. In some implementations, the process 700 further includes: forming an isolating region between adjacent pairs of independent vertical transistors along the lateral direction. The isolating region can be similar to, or same as the trench isolation 160 of FIG. 1, the isolating region 220 of FIG. 2, 306 of FIG. 3A, 410 of FIG. 4A or 4B, or the isolating region 530 of FIGS. 5A-5D. In some examples, the isolating region includes an air cavity or a cavity filled with a metal material surrounded by the isolating material.

At operation 720, a plurality of alternating stripes of the semiconductor material and an isolating material (e.g., 602 and 604 of FIGS. 6A-6B) are formed in a second side (e.g., a back side) of the semiconductor substrate along a horizontal direction (e.g., the Y direction) perpendicular to the vertical direction, the second side being opposite to the first side along the vertical direction.

In some implementations, forming the plurality of alternating stripes of the semiconductor material and the isolating material in the second side of the semiconductor substrate includes: thinning the semiconductor substrate from the second side of the semiconductor substrate to expose the plurality of alternating stripes of the semiconductor material and the isolating material, e.g., as illustrated in FIG. 6A.

At operation 730, a plurality of bit lines are formed in the second side of the semiconductor substrate. The bit line can be, e.g., the bit line 123 of FIG. 1, 202 of FIG. 2, or 302 of FIGS. 3A-3B. In some implementations, the operation 730 of forming the plurality of bit lines includes: depositing a layer of a metallic material (e.g., the metallic layer 550 of FIG. 5C) on the plurality of alternating stripes of the semiconductor material and the isolating material (732), e.g., as illustrated in FIG. 5C, and forming each bit line of the plurality of bit lines in a corresponding stripe of the semiconductor material of the plurality of alternating stripes by forming a composite conductive material based on the metallic material and the semiconductor material in the corresponding stripe of the semiconductor material (734), e.g., as illustrated in FIG. 5D or 6B.

In some implementations, forming the composite conductive material based on the metallic material and the semiconductor material in the corresponding stripe of the semiconductor material includes: annealing the metallic material and the semiconductor material, such that the metallic material reacts with the semiconductor material to form the composite conductive material. There can be no reaction between the isolating material and the metallic material deposited on the isolating material. In some implementations, the semiconductor material includes silicon, the isolating material includes oxide, and the composite conductive material includes silicide. In some examples, the metallic material includes Nickel (Ni).

In some implementations, after forming the plurality of bit lines in the second side of the semiconductor substrate, the process 700 further includes: removing a residue of the metallic material from the second side of the semiconductor substrate, e.g., by wet etching the residue of the metallic material. The residue of the metallic material can include the metallic material on the stripes of the isolating material and remaining metallic material on the bit lines.

In some implementations, e.g., as illustrated in FIG. 5B, the process 700 includes: implanting ions (e.g., N+ type ions such as P ions) into the second side of the semiconductor substrate. The composite conductive material can be formed based on the metallic material and the semiconductor material with the implanted ions.

In some implementations, implanting the ions into the second side of the semiconductor substrate includes: implanting semiconductor ions (e.g., Ge ions) into the second side of the semiconductor substrate, e.g., using Ge PAI technology, and implanting N+ type ions into the second side of the semiconductor substrate, and activating the implanted N+ type ions with the implanted semiconductor ions under an activation temperature. In some examples, the semiconductor material includes silicon, the semiconductor ions include Germanium (Ge) ions, and the N+ type ions include arsenic (As) ions or phosphorus (P) ions. The activation temperature can be lower than a nominal temperature for activating the N+ type ions without implanting the semiconductor ions. In some examples, the nominal temperature is about 900° C., and the activation temperature is in a range from about 500° C. to about 600° C.

In some implementations, thinning the semiconductor substrate from the second side of the semiconductor substrate includes: etching the semiconductor material in the second side of the semiconductor substrate and polishing a top surface of the etched semiconductor material in the second side of the semiconductor substrate, e.g., by CMP.

In some implementations, forming the plurality of strings of memory cells includes: forming the first terminal of the vertical transistor by implanting ions from the first side of the semiconductor substrate, and forming the second terminal of the vertical transistor by implanting the ions into the second side of the semiconductor substrate (e.g., as illustrated in FIG. 4B or 5B). In some examples, one of the first terminal and the second terminal is a source terminal, and the other one of the first terminal and the second terminal is a drain terminal. In some implementations, each of the plurality of bit lines is formed on the second terminal of the vertical transistor and is coupled to the second terminal of the vertical transistor, e.g., as illustrated in FIG. 1 or 3A.

In some implementations, each memory cell of the plurality of strings of memory cells further includes a capacitor (e.g., the capacitor 128 of FIG. 1) coupled to the vertical transistor, e.g., through a capacitor contact and/or VIA contact. The capacitor can be formed before forming the vertical transistor, and the capacitor can be over the vertical transistor along the vertical direction (e.g., Z direction).

In some implementations, the plurality of strings of memory cells and the plurality of bit lines are formed in an array die (e.g., the second semiconductor substrate or the array die 104 of FIG. 1). The process 700 can further include: integrating a control die (e.g., the first semiconductor structure or the control die 102 of FIG. 1) with the array die by bonding the first side of the semiconductor substrate with a front side of the control die and conductively coupling one or more conductive lines of the array die to a control circuit in the front side of the control die.

In some implementations, e.g., as illustrated in FIG. 3A, the plurality of bit lines are on a layer of the semiconductor material with implanted ions. The implanted ions can include semiconductor ions and N+ type ions. In some examples, the semiconductor material includes silicon, the semiconductor ions include Germanium (Ge) ions, the N+ type ions include arsenic (As) ions or phosphorus (P) ions, and the composite conductive material includes silicide.

In some implementations, e.g., as illustrated in FIG. 3A, a portion of the layer of the semiconductor material with the implanted ions is configured to be a terminal (e.g., the second terminal 316 of FIG. 3A, 436 of FIG. 4B, or 516 of FIGS. 5B-5D) of the vertical transistor and to be conductively coupled to a corresponding bit line.

FIG. 7B is a flow chart of another example process 750 of forming a semiconductor device. The semiconductor device can be the semiconductor device of FIG. 7A. The process 750 includes operations that can be similar to, or same as, the operations in the process 700 of FIG. 7A. The operations can be performed with any suitable order and/or any combination.

At operation 752, similar to or same as operation 710 of FIG. 7A, a plurality of strings of memory cells are formed in a first side (e.g., a front side) of a semiconductor substrate along a vertical direction (e.g., Z direction). The semiconductor substrate can include a semiconductor material (e.g., Si).

At operation 754, the semiconductor substrate is thinned from a second side (e.g., a back side) of the semiconductor substrate along the vertical direction. The second side is opposite to the first side of the semiconductor substrate. For example, as illustrated in FIG. 4B or FIG. 5A, after first terminals (e.g., the first terminals 315 of FIG. 3A, 404 of FIG. 4B, 514 of FIG. 5A) and/or gate structures (e.g., the gate structure 432 of FIG. 4B, or 518 of FIG. 5A) are formed in the first side of the semiconductor substrate, the structure is flipped back, and the semiconductor substrate can be thinned from the second side, e.g., by CMP. In some implementations, the semiconductor substrate is thinned to expose a plurality of alternating stripes of the semiconductor material and an isolating material, e.g., as shown in FIG. 6A.

At operation 756, semiconductor ions are implanted into the second side of the semiconductor substrate. The process 750 can further includes: implanting N+ type ions into the second side of the semiconductor substrate and activating the implanted N+ type ions with an activation temperature. In some examples, the semiconductor material includes silicon, the semiconductor ions include Germanium (Ge) ions, and the N+ type ions include arsenic (As) ions or phosphorus (P) ions. Before implanting the N+ type ions, the Ge pre-amorphization implantation (Ge PAI) is performed by implanting the Ge ions into the second side of the semiconductor substrate for low thermal activation. Thus, the activation temperature can be lower than a nominal temperature for activating the N+ type ions without implanting the semiconductor ions.

In some implementations, the process 750 further includes: forming a plurality of bit lines in the second side of the semiconductor substrate based on a plurality of stripes of the semiconductor material of the plurality of alternating stripes of the semiconductor material and an isolating material (e.g., oxide), e.g., operation 730 of FIG. 7A. The bit lines can be formed by depositing a layer of a metallic material on the plurality of alternating stripes of the semiconductor material and the isolating material and forming each bit line of the plurality of bit lines in a corresponding stripe of the plurality of stripes of the semiconductor material by forming a composite conductive material based on the metallic material and the semiconductor material in the corresponding stripe. The metallic material can include Nickel (Ni).

The composite conductive material can be formed by annealing the metallic material and the semiconductor material, such that the metallic material reacts with the semiconductor material to form the composite conductive material. There can be no reaction between the isolating material and the metallic material deposited on the isolating material. In some implementations, the composite conductive material is formed based on the metallic material and the semiconductor material with the activated implanted N+ ions.

In some implementations, each memory cell of the plurality of strings of memory cells includes a vertical transistor along the vertical direction. Forming the plurality of strings of memory cells includes: forming a gate terminal of the vertical transistor by depositing at least one metallic layer on an inner surface of a trench along the vertical direction; forming a first terminal of the vertical transistor by implanting N+ type ions from the first side of the semiconductor substrate; and forming a second terminal of the vertical transistor by implanting the N+ type ions into the second side of the semiconductor substrate. In some examples, the first terminal is a source terminal, and the second terminal is a drain terminal.

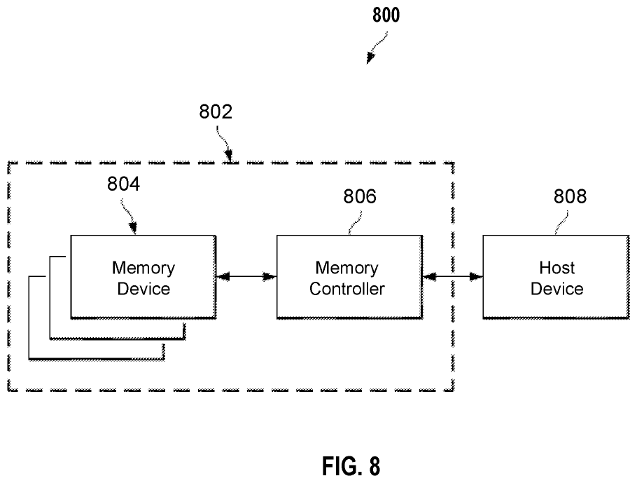

FIG. 8 illustrates a block diagram of a system 800 having one or more semiconductor devices (e.g., memory devices), according to one or more implementations of the present disclosure. The system 800 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 8, the system 800 can include a host device 808 and a memory system 802 having one or more 3D memory devices 804 and a memory controller 806. Host device 808 can include a processor of an electronic device, such as a central processing unit (CPU), or a system-on-chip (SoC), such as an application processor (AP). Host device 808 can be configured to send or receive data to or from the one or more 3D memory devices 804.

A 3D memory device 804 can be any 3D memory device disclosed herein, such as 3D memory device depicted in FIGS. 1-7B. In some implementations, a 3D memory device 804 includes a NAND Flash memory. Memory controller 806 (a.k.a., a controller circuit) is coupled to 3D memory device 804 and host device 808. Consistent with implementations of the present disclosure, 3D memory device 804 can include a plurality of conductive interconnections through a cover layer that are in contact with conductive pads in a conductive pad layer, and memory controller 806 can be coupled to 3D memory device 804 through at least one of the plurality of conductive interconnections. Memory controller 806 is configured to control 3D memory device 804. For example, memory controller 806 may be configured to operate a plurality of channel structures via word lines. Memory controller 806 can manage data stored in 3D memory device 804 and communicate with host device 808.

In some implementations, memory controller 806 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 806 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 806 can be configured to control operations of 3D memory device 804, such as read, erase, and program (or write) operations. Memory controller 806 can also be configured to manage various functions with respect to the data stored or to be stored in 3D memory device 804 including, but not limited to bad-block management, garbage collection, logical-to-physical address conversion, wear leveling, etc. In some implementations, memory controller 806 is further configured to process error correction codes (ECCs) with respect to the data read from or written to 3D memory device 804. Any other suitable functions may be performed by memory controller 806 as well, for example, formatting 3D memory device 804.

Memory controller 806 can communicate with an external device (e.g., host device 808) according to a particular communication protocol. For example, memory controller 806 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 806 and one or more 3D memory devices 804 can be integrated into various types of storage devices, for example, be included in the same package, such as a universal Flash storage (UFS) package or an eMMC package. That is, memory system 802 can be implemented and packaged into different types of end electronic products. In one example as shown in FIG. 8, memory controller 806 and a single 3D memory device 804 may be integrated into a memory card 802. Memory card 802 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for case of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−. 10%, .+−. 20%, or .+−. 30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate. The terms “operation” and “step” can be used interchangeably to describe a process.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations. Certain features that are described in this present disclosure in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

1. A method comprising:
forming a plurality of strings of memory cells in a first side of a semiconductor substrate along a vertical direction, the semiconductor substrate comprising a semiconductor material;
forming a plurality of alternating stripes of the semiconductor material and an isolating material in a second side of the semiconductor substrate along a horizontal direction perpendicular to the vertical direction, the second side being opposite to the first side along the vertical direction; and
forming a plurality of bit lines in the second side of the semiconductor substrate, wherein forming the plurality of bit lines comprises:
depositing a layer of a metallic material on the plurality of alternating stripes of the semiconductor material and the isolating material; and
forming each bit line of the plurality of bit lines in a corresponding stripe of the semiconductor material of the plurality of alternating stripes by forming a composite conductive material based on the metallic material and the semiconductor material in the corresponding stripe of the semiconductor material.

2. The method of claim 1, wherein forming the composite conductive material based on the metallic material and the semiconductor material in the corresponding stripe of the semiconductor material comprises:
annealing the metallic material and the semiconductor material, such that the metallic material reacts with the semiconductor material to form the composite conductive material.

3. The method of claim 1, wherein the semiconductor material comprises silicon, the isolating material comprises oxide, and the composite conductive material comprises silicide.

4. The method of claim 1, further comprising:
after forming the plurality of bit lines in the second side of the semiconductor substrate, removing a residue of the metallic material from the second side of the semiconductor substrate.

5. The method of claim 1, wherein forming the plurality of alternating stripes of the semiconductor material and the isolating material in the second side of the semiconductor substrate comprises:
thinning the semiconductor substrate from the second side of the semiconductor substrate to expose the plurality of alternating stripes of the semiconductor material and the isolating material,
wherein the method further comprises:
implanting ions into the second side of the semiconductor substrate, and
wherein forming the composite conductive material based on the metallic material and the semiconductor material in the corresponding stripe of the semiconductor material comprises:
forming the composite conductive material based on the metallic material and the semiconductor material with the implanted ions.

6. The method of claim 5, wherein implanting the ions into the second side of the semiconductor substrate comprises:
implanting semiconductor ions into the second side of the semiconductor substrate;
implanting N+ type ions into the second side of the semiconductor substrate; and
activating the implanted N+ type ions with the implanted semiconductor ions under an activation temperature.

7. The method of claim 6, wherein the semiconductor material comprises silicon, the semiconductor ions comprise Germanium (Ge) ions, and the N+ type ions comprise arsenic (As) ions or phosphorus (P) ions.

8. The method of claim 6, wherein the activation temperature is lower than a nominal temperature for activating the N+ type ions without implanting the semiconductor ions.

9. The method of claim 5, wherein thinning the semiconductor substrate from the second side of the semiconductor substrate comprises:
etching the semiconductor material in the second side of the semiconductor substrate; and
polishing a top surface of the etched semiconductor material in the second side of the semiconductor substrate.

10. The method of claim 5, wherein each memory cell of the plurality of strings of memory cells comprises a vertical transistor along the vertical direction, and
wherein forming the plurality of strings of memory cells comprises:
forming a gate terminal of the vertical transistor by depositing at least one metallic layer on an inner surface of a trench along the vertical direction;
forming a first terminal of the vertical transistor by implanting the ions from the first side of the semiconductor substrate; and
forming a second terminal of the vertical transistor by implanting the ions into the second side of the semiconductor substrate.

11. The method of claim 10, wherein each of the plurality of bit lines is formed on the second terminal of the vertical transistor and is coupled to the second terminal of the vertical transistor.

12. The method of claim 10, wherein each memory cell of the plurality of strings of memory cells further comprises a capacitor coupled to the vertical transistor, and
wherein forming the plurality of strings of memory cells comprises:
forming the capacitor before forming the vertical transistor, the capacitor being over the vertical transistor along the vertical direction.

13. The method of claim 10, wherein forming the plurality of strings of memory cells comprises:
forming gate terminals of a pair of independent vertical transistors in a same trench along the vertical direction, the gate terminals being separated by an isolating material along a third direction perpendicular to the vertical direction and the horizontal direction.

14. The method of claim 13, further comprising:
forming an isolating region between adjacent pairs of independent vertical transistors along the third direction.

15. The method of claim 1, wherein the plurality of strings of memory cells and the plurality of bit lines are formed in an array die, and
wherein the method further comprises:
integrating a control die with the array die by bonding the first side of the semiconductor substrate with a front side of the control die and conductively coupling one or more conductive lines of the array die to a control circuit in the front side of the control die.

16. A semiconductor device, comprising:
a plurality of strings of memory cells in a first side of a semiconductor substrate along a vertical direction, the semiconductor substrate comprising a semiconductor material; and
a plurality of bit lines in a second side of the semiconductor substrate, the second side being opposite to the first side along the vertical direction, wherein adjacent bit lines of the plurality of bit lines are separated by an isolating material along a horizontal direction perpendicular to the vertical direction,
wherein the plurality of bit lines are made of a composite conductive material that is based on the semiconductor material, and wherein the plurality of bit lines are on a layer of the semiconductor material with implanted ions.

17. The semiconductor device of claim 16, wherein the implanted ions comprise semiconductor ions and N+ type ions.

18. The semiconductor device of claim 16, wherein each memory cell of the plurality of strings of memory cells comprises a vertical transistor along the vertical direction, and
wherein a portion of the layer of the semiconductor material with the implanted ions is configured to be a terminal of the vertical transistor and to be conductively coupled to a corresponding bit line.

19. The semiconductor device of claim 18, wherein gate terminals of a pair of independent vertical transistors are in a same trench along the vertical direction and separated by an isolating material along a third direction perpendicular to the vertical direction and the horizontal direction, and
wherein an isolating region is between adjacent pairs of independent vertical transistors along the third direction.

20. A system, comprising:
a memory device comprising:
an array structure comprising a plurality of strings of memory cells in a first side of a semiconductor substrate along a vertical direction, the semiconductor substrate comprising a semiconductor material; and
a plurality of bit lines in a second side of the semiconductor substrate, the second side being opposite to the first side along the vertical direction, wherein adjacent bit lines of the plurality of bit lines are separated by an isolating material along a horizontal direction perpendicular to the vertical direction, wherein the plurality of bit lines are made of a composite conductive material that is based on the semiconductor material, and wherein the plurality of bit lines are on a layer of the semiconductor material with implanted ions; and
a controller coupled to the memory device and configured to control the memory device.
